(19) United States
(12) Patent Application Publication
(10) Pub. No.: US 2025/0068785 A1
(43) Pub. Date: Feb. 27, 2025

(54) METHOD FOR DETERMINING A RISK OF LANDING FAILURE

(71) Applicant: Airbus Operations (S.A.S.), Toulouse (FR)

(72) Inventors: Thierry BOURRET, Toulouse (FR); Jean MULLER, Toulouse (FR); Lilian RONCERAY, Toulouse (FR); Nils CAHINGT, Toulouse (FR)

(21) Appl. No.: 18/799,313

(22) Filed: Aug. 9, 2024

(30) Foreign Application Priority Data
Aug. 22, 2023 (FR) 2308848

(51) Int. Cl. G06F 30/15; G06F 30/27

(52) U.S. Cl. CPC G06F 30/15; G06F 30/27

(57) ABSTRACT

A method for determining a risk of landing failure of an aircraft on a landing location is based on a reference table constructed by making a selection of a set of values of M variables representative of landing conditions independent of potential turbulences, uniformly between a minimum value and a maximum value of each variable, performing a number P of closed-loop simulations by applying random turbulence conditions, from the set of values of the M variables, calculating a mean and a standard deviation of touchdown parameters from the P closed-loop simulations, and by complementing the reference table on each iteration for a number N of sets of values of the M variables. Next, the reference table is used to determine the risk of landing failure, in light of envisaged landing conditions.

### TECHNICAL FIELD

The disclosure herein relates to a method and a system for determining a risk of landing failure of an aircraft on a landing location.

### BACKGROUND

There are tools for determining a risk of landing failure, as for example used in automatic landing systems in aircraft. These tools process by closed-loop simulations variables representative of landing conditions to which is added a model of turbulences intended to reproduce turbulence effects encountered on landing. These give estimations of «touchdown parameters» which, when compared to acceptability limit values, define a risk of landing failure.

Each of these variables is characterized by a probability distribution. For example, the mean lateral wind speed follows a Gaussian probability distribution. For example again, the runway length follows a specific probability distribution between 1500 m and 4500 m. It is particularly important to note that, in these tools, the probability distribution of each variable is established with respect to feedback over an entire fleet of aircraft.

It is then possible for these tools to determine a mean risk, over the entire fleet of aircraft, of landing failure on all the possible landing locations for the fleet of aircraft.

It may however be desirable to determine a risk of landing failure more specifically for an aircraft on a particular landing location in particular landing conditions. In which case, it is also desirable to provide a solution which is quick to use.

### SUMMARY

A method is thus proposed here for determining a risk of landing failure of an aircraft on a particular landing location, wherein a system in electronic circuitry form constructs a reference table as follows: making a selection of a set of values of M variables representative of landing conditions independent of potential turbulences on landing; performing a number P of closed-loop simulations by applying random turbulence conditions according to a predefined model of turbulences, from the set of values of the M variables which has been selected; calculating a mean and a standard deviation of touchdown parameters from the P closed-loop simulations; complementing the reference table by adding a row to the reference table, each row storing the mean and the standard deviation of each touchdown parameter, as well as the set of values of the M variables which has made it possible to obtain the mean and the standard deviation; reiterating for a number N of sets of values of the M variables, the values of each variable being chosen uniformly between a minimum value and a maximum value of the variable. The method is such that it further comprises: using the reference table to determine the risk of landing failure of the aircraft on the particular landing location, in light of envisaged landing conditions, the risk of landing failure being a probability that at least one of the touchdown parameters crosses an authorized limit for the touchdown parameter.

Thus, a risk of landing failure can be specifically determined for an aircraft on a particular landing location in particular landing conditions. In addition, the construction of the reference table makes it possible to rapidly determine such a risk of landing failure for different landing locations (distinguished from one another in the reference table) and particular landing conditions, by virtue of the fact that the closed-loop simulations are performed upstream, during the construction of the reference table.

In a first approach, using the reference table comprises: using the reference table to perform a phase of learning of a deep learning model, the learning being such that the conditions recorded in the reference table are entered as input of the deep learning model in order to predict the corresponding mean and standard deviation values for each touchdown parameter. And, in a phase of usage of the deep learning model after the learning phase, the method comprises: obtaining the conditions envisaged on landing, expressed by corresponding values of the M variables; injecting the conditions envisaged on landing as input of the deep learning model; recovering as output of the deep learning model expected mean and standard deviation values for each touchdown parameter; determining the risk of landing failure for the aircraft on the particular landing location, by using the mean and the standard deviation recovered for each touchdown parameter.

In a second approach, using the reference table comprises: obtaining the conditions envisaged on landing, expressed by corresponding values of the M variables; searching for a set of conditions recorded in the reference table that is the closest to the conditions envisaged on landing; recovering from the reference table expected mean and standard deviation values for each touchdown parameter, which have been recorded correlated with the set of conditions closest to the conditions envisaged on landing; and determining the risk of landing failure for the aircraft on the particular landing location, by using the mean and the standard deviation recovered for each touchdown parameter.

In a third approach, using the reference table comprises: obtaining the conditions envisaged on landing, expressed by corresponding values of the M variables; searching for the sets of conditions recorded in the reference table which are the closest to the conditions envisaged on landing; recovering a set of expected mean and standard deviation values which has been recorded correlated with each set of conditions from among the sets of conditions that are the closest to the conditions envisaged on landing; performing an interpolation of the sets of expected mean and standard deviation values recovered; and determining a risk of landing failure for the aircraft on the particular landing location, by using the mean and the standard deviation, for each touchdown parameter, which result from the interpolation performed.

In a particular embodiment, the method further comprises: eliminating conditions which have the least influence on the touchdown parameters compared to the other conditions, to reduce N to Q, and replacing the reference table obtained with the N sets of values of the M variables with a new reference table obtained with the Q sets of values of the M variables.

In a particular embodiment, the method further comprises: analyzing relationships of dependency of the touchdown parameters with the M variables; determining which linear combination of the M variables most influences the touchdown parameters; and replacing the reference table obtained with the N sets of values of the M variables with a new reference table obtained with Q sets of the linear combination of the M variables, and wherein the reference table is used by applying the same linear combination to the conditions envisaged on landing.

In a particular embodiment, the method further comprises: determining which variables from among the M variables most influence the touchdown parameters; and replacing the reference table obtained with the N sets of values of the M variables selected uniformly with a new reference table obtained by increasing a panel of values of the variables which most influence the touchdown parameters and by reducing a panel of values of the variables which least influence the touchdown parameters.

In a particular embodiment, the method is implemented in the context of aircraft piloting assistance, to make a selection of a landing location from among candidate landing locations.

In a particular embodiment, the method is implemented in the context of aircraft piloting assistance, to monitor a change in risk of landing failure at destination.

Also disclosed here is a system configured to determine a risk of landing failure of an aircraft on a particular landing location, the system being in electronic circuitry form, the electronic circuitry being configured to construct a reference table as follows: making a selection of a set of values of M variables representative of landing conditions independent of potential turbulences on landing; performing a number P of closed-loop simulations by applying random turbulence conditions according to a predefined model of turbulences, from the set of values of the M variables that has been selected; calculating a mean and a standard deviation of touchdown parameters from the P closed-loop simulations; complementing the reference table by adding a row to the reference table, each row storing the mean and the standard deviation of each touchdown parameter, as well as the set of values of the M variables that has made it possible to obtain the mean and the standard deviation; reiterating for a number N of sets of values of the M variables, the values of each variable being chosen uniformly between a minimum value and a maximum value of the variable. And, the electronic circuitry being further configured to use the reference table to determine the risk of landing failure of the aircraft on the particular landing location, in light of landing conditions envisaged, the risk of landing failure being a probability that at least one of the touchdown parameters crosses an authorized limit for the touchdown parameter.

### BRIEF DESCRIPTION OF THE DRAWINGS

The features of the disclosure herein mentioned above, and others, will become more clearly apparent on reading the following description of at least one example embodiment, the description being given in relation to the attached drawings, in which:

FIG. 1 schematically illustrates an algorithm for constructing a reference table making it possible to determine a risk of landing failure;

FIG. 2 schematically illustrates an example of hardware system arrangement suitable for constructing and/or using the reference table;

FIG. 3 schematically illustrates an algorithm for using the reference table to determine a risk of landing failure, according to a first embodiment;

FIG. 4 schematically illustrates an algorithm for using the reference table to determine a risk of landing failure, according to a second embodiment;

FIG. 5 schematically illustrates an algorithm for using the reference table to determine a risk of landing failure, according to a third embodiment;

FIG. 6 schematically illustrates an aircraft piloting assistance algorithm that makes it possible to make a landing location selection;

FIG. 7 schematically illustrates an aircraft piloting assistance algorithm that makes it possible to monitor a change in risk of landing failure; and

FIG. 8 schematically illustrates, in a side view, an aircraft equipped with a piloting assistance system.

### DETAILED DESCRIPTION

As detailed hereinbelow, a system is specifically configured to construct and use a reference table in order to make it possible to determine a risk of landing failure for a particular aircraft on a particular landing runway.

The construction of the reference table is, in at least one embodiment, done in a first part of the system, for example by an aircraft manufacturer; and the use of the reference table is done in a second part of the system, for example on board an aircraft or in premises of an airline, to determine the risk of landing failure for the aircraft on a particular landing runway.

The construction of the reference table is, in at least one other embodiment, done in a first part of the system, for example by an aircraft manufacturer; the use of the reference table is also done in this first part of the system to obtain a deep learning model derived from the reference table, and it is this deep learning model which is then used in a second part of the system, for example on board an aircraft or in premises of an airline, to determine the risk of landing failure for the aircraft on a particular landing runway.

The construction of the reference table and its use to determine the risk of landing failure for a particular aircraft on a particular landing runway are, in yet at least another embodiment, done in a same device, for example in a same computing system.

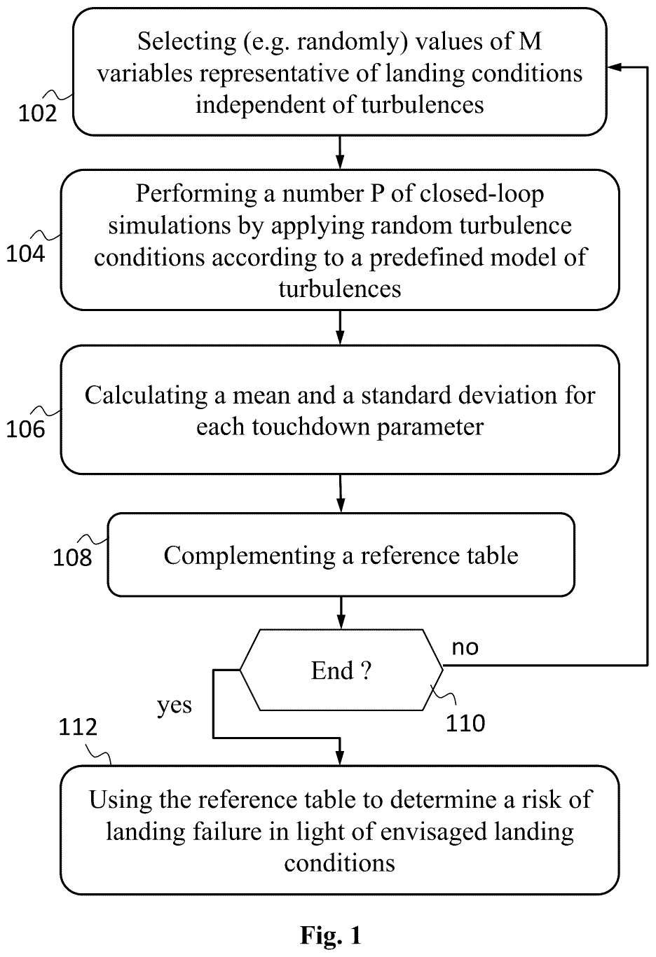

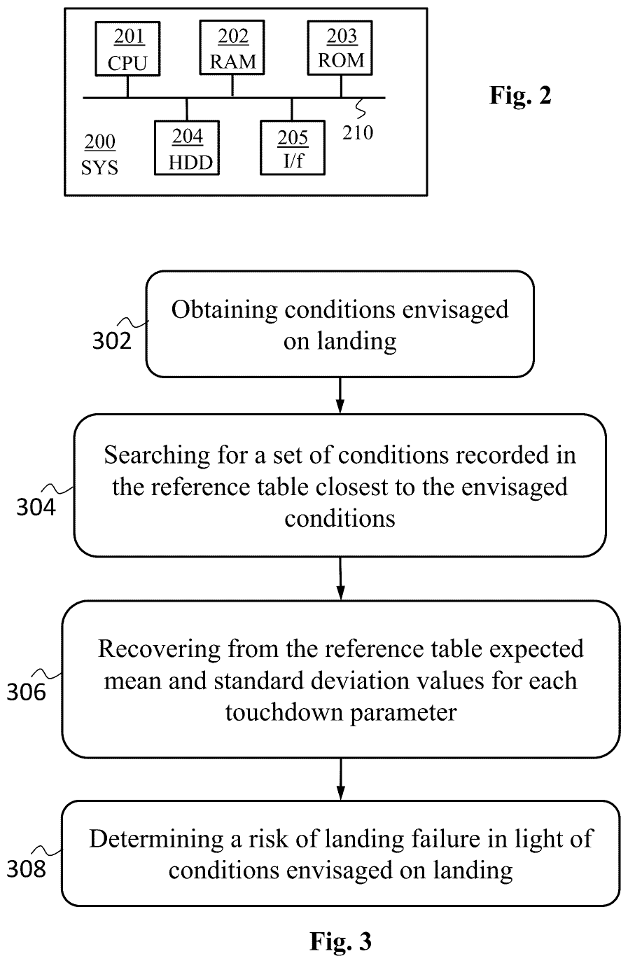

FIG. 1 schematically illustrates an algorithm for constructing a reference table that makes it possible to determine a risk of landing failure for an aircraft on a landing runway of an airport. The algorithm of FIG. 1 is implemented by a system in electronic circuitry form, an example arrangement of which is presented hereinbelow in relation to FIG. 2.

In a step 102, the system makes a selection of a set of values of M variables representative of landing conditions independent of potential turbulences on landing. In a particular embodiment, the selection of the set of values of the M variables is done randomly. In another particular embodiment, the selection of the set of values of the M variables is done by regular meshing, that is to say a regular distribution of the values selected for each variable.

As described hereinbelow, multiple iterations will be performed with different sets of values of M variables. The values (panel of values) of each variable are chosen uniformly between a minimum value and a maximum value of the variable. Thus, the probability distributions of the M variables are not established with respect to feedback over an entire fleet of aircraft. That makes it possible to have all the possible combinations of the M variables which, by observing the in-service data, may never occur.

In a particular embodiment, the variables representative of landing conditions include:
mean longitudinal wind speed;
mean lateral wind speed;
weight of the aircraft;
position of the center of gravity of the aircraft;
temperature variation, by comparison to the ISA («International Standard Atmosphere») standard;
altitude of the landing runway;
length of the landing runway;
slope of the landing runway;
descent trajectory slope, or «glide slope»;
descent trajectory reference point height, or «glide reference point height»;
misalignment of radiofrequency guidance means («localizer»).

Thus, for example, M=11.

In a step 104, the system performs a number P of closed-loop simulations by applying random turbulence conditions according to a predefined model of turbulences, from the set of values of the M variables which has been selected. For example, P=200. The amplitude of the turbulences depends typically on the wind speed measured at the airport control tower («tower wind») which, for example, depends on the mean longitudinal and lateral wind speed.

In a step 106, the system calculates, according to the P closed-loop simulations, a mean and a standard deviation for each parameter of a set of «touchdown parameters».

In a particular embodiment, the touchdown parameters are:
the positioning of the longitudinal touchdown point (in the axis of the landing runway),
the positioning of the lateral touchdown point (at right angles to the axis of the landing runway),
the landing gear load on impact,
the lateral angle of inclination, or «bank angle»,
the ground clearance of the rear part of the fuselage on touchdown,
the lateral slip, or «side slip», on touchdown.

In a step 108, the system complements a reference table. On each iteration (steps 102 to 106), the system adds a row to the reference table. Each row stores the mean and the standard deviation of each touchdown parameter, as well as the conditions in which they have been obtained, that is to say the values of the M variables which have made it possible to obtain them.

In a step 110, the system determines whether a sufficient number of entries has been obtained in the reference table. For example, N=35,000 different conditions are tested, namely N sets of values of the M variables. If such is the case, a step 112 is performed; otherwise, the step 102 is reiterated with a selection (e.g., random) of a new set of values of the M variables, and therefore new landing conditions (independently of potential turbulences on landing) are selected. The reiterations of the step 102 are such that the values (panel of values) of each variable are chosen (e.g., randomly) uniformly between a minimum value and a maximum value of the variable. For example, to simplify the closed-loop simulations, a discrete subset of the values of each variable can be used (e.g., the minimum value, the maximum value and some intermediate values).

In a step 112, the system uses the reference table to determine a risk of landing failure in light of envisaged landing conditions. The risk of landing failure is a probability that at least one of the touchdown parameters crosses an authorized limit for the touchdown parameter. One example would be a lateral touchdown that is off-center by more than 21 m for an «outboard landing gear» on a landing runway of a width equal to 45 m.

The reference table (or a deep learning model derived from the reference table, as detailed hereinbelow) makes it possible to rapidly determine the risk of landing failure, since the closed-loop simulations have been performed upstream (to construct the reference table). And, to determine a risk of landing failure specifically for new landing conditions, it is sufficient to re-use the reference table, without having to execute the closed-loop simulations again.

Embodiments of a use of the reference table to determine such a risk of landing failure are detailed hereinbelow, more particularly in relation to FIGS. 3 to 7.

In a particular embodiment, the system analyzes dependency relationships of the touchdown parameters with the M variables. This analysis can be a correlation analysis, for example of Pearson or Spearman type. This analysis can be a «Principal Components Analysis» or PCA. This analysis therefore makes it possible to reduce the number of different conditions tested in simulation by eliminating conditions which have the least influence (i.e., which have no or little influence) on the touchdown parameters (reduction from N to Q) with respect to the other conditions. The system can then replace the reference table obtained with the N conditions with a new reference table obtained by reiterating the algorithm of FIG. 1 with the Q conditions.

In a variant, the analysis allows the system to determine which linear combination of the M variables (first principal component) most influences the touchdown parameters. The system can then replace the reference table obtained with the N conditions with a new reference table obtained by reiterating the algorithm of FIG. 1 with Q sets of the linear combination of the M variables. The reference table must then be used by applying the same linear combination to conditions envisaged at destination.

In another variant, the analysis allows the system to determine which variables have the most influence on the touchdown parameters. Then, rather than choosing the values of each variable uniformly, the system can reiterate the algorithm of FIG. 1 by increasing the panel of values of the variables which most influence the touchdown parameters and by reducing the panel of values of the variables which least influence the touchdown parameters.

FIG. 2 schematically illustrates an example of hardware platform suitable for implementing the system, referenced SYS 200 in FIG. 2, in electronic circuitry form. The system can comprise several cooperating hardware platforms, for example a first such hardware platform for the purpose of constructing the reference table and a second such hardware platform for the purpose of using the reference table.

The hardware platform then comprises, linked by a communication bus 210: a processor or CPU («Central Processing Unit») 201; a RAM («Random Access Memory») memory 202; a read-only memory 203, for example of ROM («Read Only Memory») or EEPROM («Electrically-Erasable Programmable ROM») type or of Flash type; a storage unit, such as a hard disk HDD («Hard Disk Drive») 204, or a storage medium reader, such as an SD («Secure Digital») card reader; and an interface manager I/f 205.

The interface manager I/f 205 allows the hardware platform to interact with peripheral devices, such as human-machine interface peripheral devices (input, display of simulation results, etc.) and/or with a communication network.

The processor 201 is capable of executing instructions loaded into the random-access memory 202 from the read-only memory 203, from an external memory, from a storage medium (such as an SD card), or from a communication network. When the hardware platform is powered up, the processor 201 is capable of reading instructions from the random-access memory 202 and executing them. These instructions form a computer program causing the implementation, by the processor 201, of all or some of the steps and algorithms described here.

All or some of the steps and algorithms described here can thus be implemented in software form by the execution of a set of instructions by a programmable machine, for example a processor of DSP («Digital Signal Processor») type or a microcontroller, or be implemented in hardware form by a machine or a dedicated electronic component («chip») or a dedicated set of electronic components («chipset»). Generally, the system SYS 200 comprises electronic circuitry adapted and configured to implement the steps and algorithms described here.

The system SYS 200 can be composed of a single hardware platform as described hereinabove, by which the reference table is constructed and used. Thus, the system SYS 200 can be a computerized system in place in premises of an aircraft manufacturer or an airline.

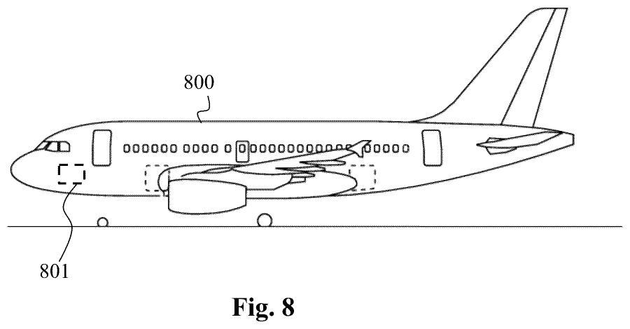

The system SYS 200 can be composed of a set of such hardware platforms. A first hardware platform, by which the reference table is constructed, can be a computerized system in place in premises of an aircraft manufacturer or an airline; and a second hardware platform, by which the reference table is used, can be a system embedded in an aircraft or in premises of an airline. The reference table is then for example transmitted from the first hardware platform to the second hardware platform by communication means. FIG. 8 thus schematically illustrates, in a side view, an aircraft 800 embedding such a second hardware platform 801, by which the reference table is used. The second hardware platform 801 is for example incorporated in the avionics of the aircraft 800.

FIG. 3 schematically illustrates an algorithm of use of the reference table to determine a risk of landing failure for an aircraft on a landing runway of an airport, according to a first embodiment. The reference table is constructed as explained hereinabove in relation to FIG. 1.

In a step 302, the system obtains conditions envisaged on landing. The conditions envisaged on landing are expressed by corresponding values of the M variables.

In a step 304, the system searches for a set of conditions recorded in the reference table that is the closest to the conditions envisaged on landing.

In a step 306, the system recovers from the reference table expected mean and standard deviation values for each touchdown parameter, which have been recorded correlated with the set of conditions derived from the step 304.

In a step 308, the system determines a risk of landing failure for the aircraft on the landing runway of the airport concerned, by using the mean and the standard deviation, for each touchdown parameter, recovered in the step 306.

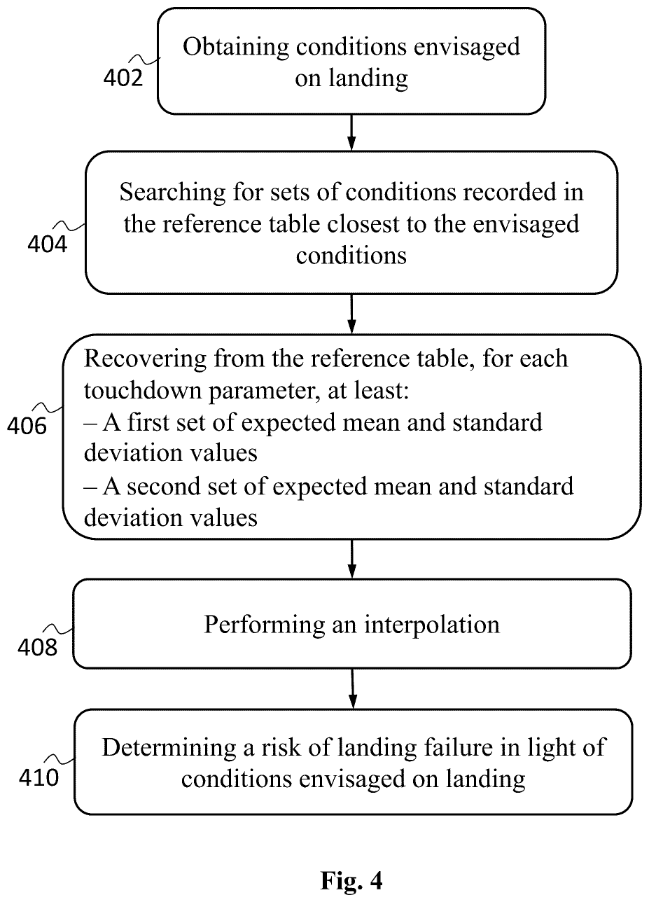

FIG. 4 schematically illustrates an algorithm of use of the reference table to determine a risk of landing failure for an aircraft on a landing runway of an airport, according to a second embodiment. The reference table is constructed as explained hereinabove in relation to FIG. 1.

In a step 402, the system obtains conditions envisaged on landing. The conditions envisaged on landing are expressed by corresponding values of the M variables.

In a step 404, the system searches for the sets of conditions recorded in the reference table which are the closest to the conditions envisaged on landing. For example, the system searches for the two sets of conditions recorded in the reference table which are the closest to the conditions envisaged on landing.

In a step 406, the system recovers from the reference table, for each touchdown parameter, at least:
a first set of expected mean and standard deviation values; and
a second set of expected mean and standard deviation values.

The system thus recovers a set of expected mean and standard deviation values which has been recorded correlated with each set of conditions derived from the step 404.

In a step 408, the system performs an interpolation (for example, a linear interpolation) of the sets of expected mean and standard deviation values recovered in the step 406.

In a step 410, the system determines a risk of landing failure for the aircraft on the landing runway of the airport concerned, by using the mean and the standard deviation, for each touchdown parameter, which result from the interpolation performed in the step 408.

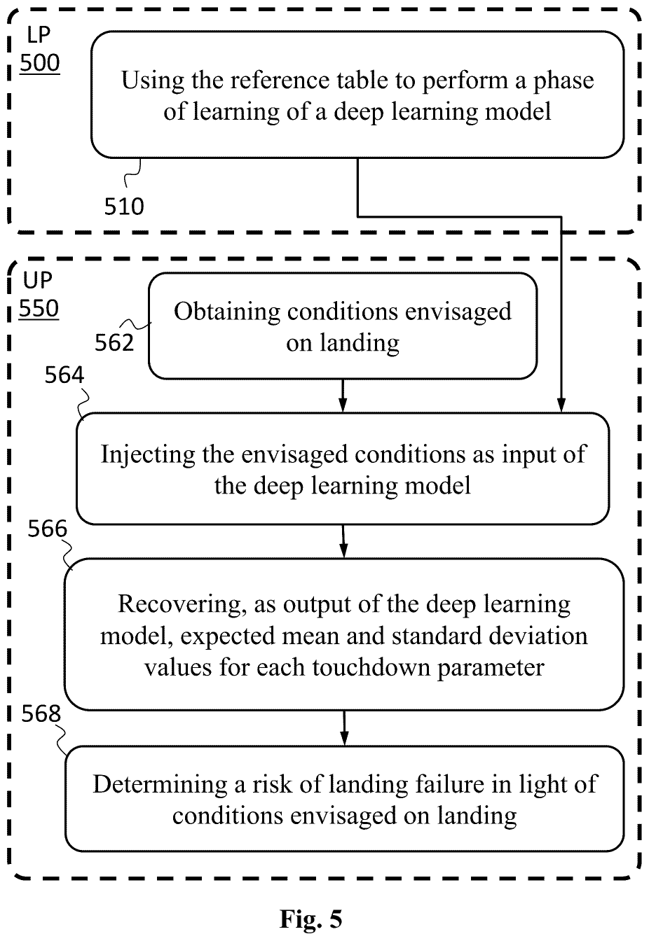

FIG. 5 schematically illustrates an algorithm of use of the reference table to determine a risk of landing failure for an aircraft on a landing runway of an airport, according to a third embodiment. The reference table is constructed as explained hereinabove in relation to FIG. 1.

The algorithm of FIG. 5 relies on a use of a «Deep Learning Model». Thus the algorithm is broken down into two phases: a learning phase LP 500 (training and validation) and a usage phase UP 550. The deep learning model is for example a two-layer neural network with a size of 10 to 30 neurons.

Thus, in a step 510, the system uses the reference table to perform the phase of learning of the deep learning model. The learning is such that the conditions recorded in the reference table are entered as input of the deep learning model in order to predict the corresponding mean and standard deviation values for each touchdown parameter. It should be noted that, in a particular embodiment, the reference table used is the one obtained following the above-mentioned analysis of the dependency relationships.

Once the learning is finished, the deep learning model can be used to determine the risk of landing failure for the aircraft on the landing runway of the airport concerned.

Thus, in a step 562, the system obtains conditions envisaged on landing. The conditions envisaged on landing are expressed by corresponding values of the M variables.

In a step 564, the system injects the conditions envisaged on landing as input of the deep learning model.

In a step 566, the system recovers as output of the deep learning model expected mean and standard deviation values for each touchdown parameter.

In a step 568, the system determines a risk of landing failure for the aircraft on the landing runway of the airport concerned, by using the mean and the standard deviation, for each touchdown parameter, which have been recovered in the step 566.

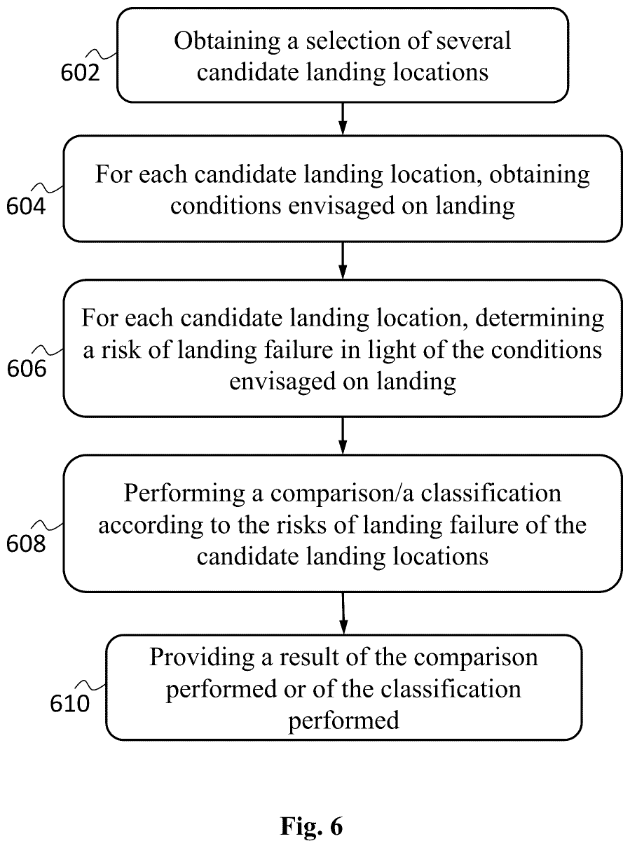

FIG. 6 schematically illustrates an aircraft piloting assistance algorithm making it possible to make a landing location selection.

In a step 602, the system obtains a selection of several candidate landing locations. According to a first example, when the aircraft is diverted, the avionics of the aircraft determines a set of potential landing locations (alternative airports) within a predetermined radius of the aircraft in flight, and indicates it to the system. According to a second example, the selection is made by the crew of the aircraft via a human-machine interface of the cockpit of the aircraft.

In a step 604, the system obtains, for each candidate landing location, conditions envisaged on landing. The conditions envisaged on landing are expressed by corresponding values of the M variables. The conditions envisaged on landing will typically differ from one landing location to another.

In a step 606, the system determines, for each candidate landing location, a risk of landing failure in light of the conditions envisaged on landing (for the candidate landing location). The determination of the risk of landing failure is made as previously described, by using the reference table (possibly through the above-mentioned deep learning model).

In a step 608, the system performs a comparison, or a classification, of the candidate landing locations according to the risk of landing failure determined for each of the candidate landing locations.

In a step 610, the system supplies a result of the comparison performed or of the classification performed. According to a first example, the system displays, on a screen of a human-machine interface of the cockpit of the aircraft, the candidate landing location which presents the lowest risk of landing failure. According to a second example, the system displays, on a screen of a human-machine interface of the cockpit of the aircraft, the candidate landing locations by descending order of risk of landing failure.

In a particular embodiment, the system performs a filtering so as to exclude any candidate landing location which presents a risk of landing failure greater than a predetermined threshold TH representative of an unacceptable risk of failure. For example, the threshold TH is set at 10⁻⁶ or at 10⁻⁷.

In a particular embodiment, the algorithm of FIG. 6 is followed by aircraft piloting operations along an approach trajectory of a landing runway selected from among several candidate landing runways as a function of the risks of landing failure obtained for the candidate landing runways.

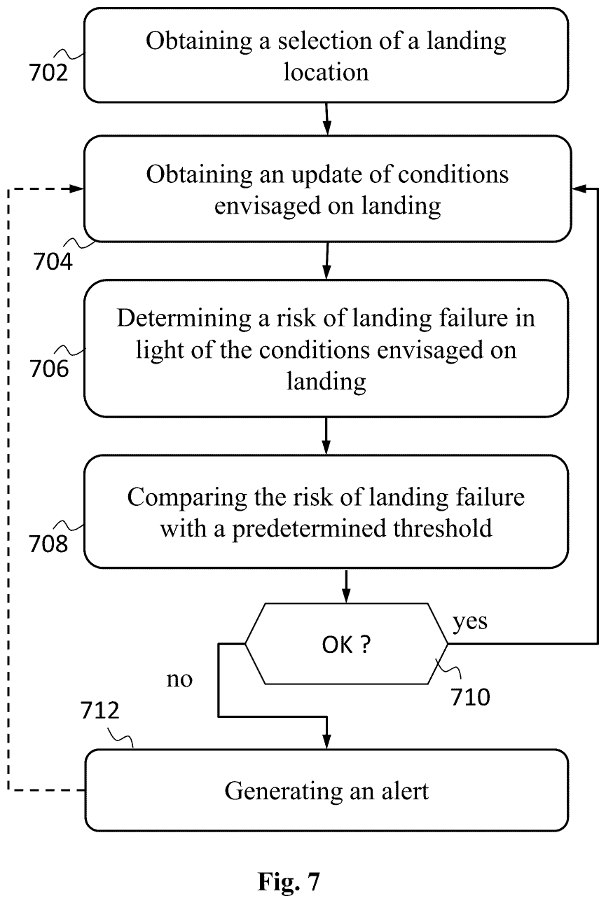

FIG. 7 schematically illustrates an aircraft piloting assistance algorithm that makes it possible to monitor a change in risk of landing failure at destination.

In a step 702, the system obtains a selection of a landing location. According to a first example, the avionics of the aircraft indicates to the system the destination airport of the aircraft in flight. According to a second example, the selection is made by the crew of the aircraft via a human-machine interface of the cockpit of the aircraft.

In a step 704, the system obtains an update of conditions envisaged on landing on the selected landing location. The update can originate from sensor data and/or from computers embedded in the aircraft and/or from data (e.g., meteorological data at destination) received by air/ground communication.

In a step 706, the system determines a risk of landing failure in light of the conditions envisaged on landing, for the selected landing location. The determination of the risk of landing failure is made as previously described, by using the reference table (possibly through the above-mentioned deep learning model).

In a step 708, the system compares the risk of landing failure with the predetermined threshold TH already mentioned.

In a step 710, the system checks to see if the result of the comparison indicates that the risk of landing failure is less than the predetermined threshold. If such is the case, the system sets itself to await a new update of the conditions envisaged on landing in the step 704; otherwise, a step 712 is performed.

In the step 712, the system generates an alert. According to a first example, the system generates an audible and/or visual alert through a human-machine interface of the cockpit of the aircraft. According to a first example, the system transmits an alert message by air/ground communication.

While at least one example embodiment of the invention(s) is disclosed herein, it should be understood that modifications, substitutions, and alternatives may be apparent to one of ordinary skill in the art and can be made without departing from the scope of this disclosure. This disclosure is intended to cover any adaptations or variations of the example embodiment(s). In addition, in this disclosure, the terms “comprise” or “comprising” do not exclude other elements or steps, the terms “a”, “an” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. A method for determining a risk of landing failure of an aircraft on a landing location, wherein a system in electronic circuitry form constructs a reference table by:
making a selection of a set of values of M variables representative of landing conditions independent of potential turbulences on landing;
performing a number P of closed-loop simulations by applying random turbulence conditions according to a predefined model of turbulences, from the set of values of the M variables which has been selected;
calculating a mean and a standard deviation of touchdown parameters from the P closed-loop simulations;
complementing the reference table by adding a row to the reference table, each row storing the mean and the standard deviation of each touchdown parameter, as well as the set of values of the M variables which has made it possible to obtain the mean and the standard deviation;
reiterating for a number N of sets of values of the M variables, the values of each variable being chosen uniformly between a minimum value and a maximum value of the variable; and
using the reference table to determine the risk of landing failure of the aircraft on the landing location, in light of envisaged landing conditions, the risk of landing failure being a probability that at least one of the touchdown parameters crosses an authorized limit for the touchdown parameter.

2. The method according to claim 1, wherein using the reference table comprises:
using the reference table to perform a phase of learning of a deep learning model, the learning being such that conditions recorded in the reference table are entered as input of the deep learning model in order to predict corresponding mean and standard deviation values for each touchdown parameter;
and, in a phase of usage of the deep learning model after the learning phase:
obtaining the conditions envisaged on landing expressed by corresponding values of the M variables;
injecting the conditions envisaged on landing as input of the deep learning model;
recovering as output of the deep learning model expected mean and standard deviation values for each touchdown parameter;
determining the risk of landing failure for the aircraft on the landing location by using the mean and the standard deviation recovered for each touchdown parameter.

3. The method according to claim 1, wherein using the reference table comprises:
obtaining the conditions envisaged on landing, expressed by corresponding values of the M variables;
searching for a set of conditions recorded in the reference table that is closest to the conditions envisaged on landing;
recovering from the reference table expected mean and standard deviation values for each touchdown parameter, which have been recorded correlated with the set of conditions closest to the conditions envisaged on landing; and
determining the risk of landing failure for the aircraft on the landing location, by using the mean and standard deviation recovered for each touchdown parameter.

4. The method according to claim 1, wherein using the reference table comprises:
obtaining the conditions envisaged on landing, expressed by corresponding values of the M variables;
searching for sets of conditions recorded in the reference table which are closest to the conditions envisaged on landing;
recovering a set of expected mean and standard deviation values which has been recorded correlated with each set of conditions from among the sets of conditions closest to the conditions envisaged on landing;
performing an interpolation of the sets of expected mean and standard deviation values recovered; and
determining a risk of landing failure for the aircraft on the landing location by using the mean and the standard deviation, for each touchdown parameter, which result from the interpolation performed.

5. The method according to claim 1, further comprising:
eliminating conditions which have a least influence on the touchdown parameters with respect to the other conditions, to reduce N to Q; and
replacing the reference table obtained with the N sets of values of the M variables with a new reference table obtained with the Q sets of values of the M variables.

6. The method according to claim 1, further comprising:
analyzing relationships of dependency of the touchdown parameters with the M variables;
determining which linear combination of the M variables most influences the touchdown parameters;
replacing the reference table obtained with the N sets of values of the M variables with a new reference table obtained with Q sets of the linear combination of the M variables, and wherein the reference table is used by applying a same linear combination to the conditions envisaged on landing.

7. The method according to claim 1, further comprising:
determining which variables from among the M variables most influence the touchdown parameters;
replacing the reference table obtained with the N sets of values of the M variables selected uniformly with a new reference table obtained by increasing a panel of values of the variables which most influence the touchdown parameters and by reducing a panel of values of the variables which least influence the touchdown parameters.

8. The method according to claim 1, implemented in a context of aircraft piloting assistance, for making a selection of a landing location from among candidate landing locations.

9. The method according to claim 1, implemented in a context of aircraft piloting assistance, for monitoring a change in risk of landing failure at destination.

10. A system configured to determine a risk of landing failure of an aircraft on a landing location, the system being in electronic circuitry form, the electronic circuitry being configured to construct a reference table by:
making a selection of a set of values of M variables representative of landing conditions independent of potential turbulences on landing;
performing a number P of closed-loop simulations by applying random turbulence conditions according to a predefined model of turbulences, from the set of values of the M variables which has been selected;
calculating a mean and a standard deviation of touchdown parameters from the P closed-loop simulations;
complementing the reference table by adding a row to the reference table, each row storing the mean and the standard deviation of each touchdown parameter, as well as the set of values of the M variables which has made it possible to obtain the mean and the standard deviation;
reiterating for a number N of sets of values of the M variables, the values of each variable being chosen uniformly between a minimum value and a maximum value of the variable;
and the electronic circuitry being further configured to:
use the reference table to determine the risk of landing failure of the aircraft on the landing location, in light of envisaged landing conditions, the risk of landing failure being a probability that at least one of the touchdown parameters crosses an authorized limit for the touchdown parameter.
